(19) United States
(12) Patent Application Publication
(10) Pub. No.: US 2025/0219007 A1
(43) Pub. Date: Jul. 3, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Hiroya SANNAI, Tokyo (JP); Yuji IMOTO, Tokyo (JP); Naohiro OGUSHI, Tokyo (JP)

(73) Assignee: Mitsubishi Electric Corporation, Tokyo (JP)

(21) Appl. No.: 18/850,310

(22) PCT Filed: Apr. 20, 2022
(86) PCT No.: PCT/JP2022/018307

§ 371 Date: Sep. 24, 2024

(51) Int. Cl. H01L 23/00; H01L 23/495

(52) U.S. Cl. CPC H01L 24/32; H01L 23/49541; H01L 24/29; H01L 24/33; H01L 24/83; H01L 2224/29124; H01L 2224/32225; H01L 2224/33181; H01L 2224/83203

(57) ABSTRACT

A semiconductor device includes an insulating substrate, a semiconductor element bonded to the insulating substrate, and an inner wiring member bonded to the semiconductor element. The insulating substrate includes a conductive pattern on an upper surface. The semiconductor element includes an upper surface electrode on an upper surface and a lower surface electrode on a lower surface, and the lower surface electrode is bonded to the conductive pattern of the insulating substrate. The inner wiring member is bonded to the upper surface electrode of the semiconductor element. Both bonding of the lower surface electrode and the conductive pattern and bonding of the upper surface electrode and the inner wiring member are performed by an Al brazing material.

### TECHNICAL FIELD

The present disclosure relates to a semiconductor device, and particular to a technique of connecting a wiring member to a plurality of semiconductor elements mounted on a substrate at the same time.

### BACKGROUND ART

Known is a semiconductor device having a configuration that a plurality of semiconductor elements such as an insulated gate bipolar transistor (IGBT), a metal oxide semiconductor field-effect transistor (MOSFET), or a diode, for example, are mounted on a substrate. An upper surface electrode and a lower surface electrode each made of metal are formed on a front surface (referred to as “the upper surface” hereinafter) and a back surface (referred to as “the lower surface” hereinafter) of the semiconductor element, respectively, the upper surface electrode is bonded to a wiring member, a lower surface electrode is bonded to a substrate, and a brazing material such as solder is generally used for bonding them (for example, Patent Document 1 hereinafter). Also proposed is bonding of the lower surface electrode and the substrate using a brazing material (referred to as “the Al brazing material” hereinafter) made of aluminum (Al) having higher heat radiation properties and higher heat resistance than solder as a main component (for example, Patent Document 2 hereinafter).

### PRIOR ART DOCUMENTS

### Patent Document(s)

Patent Document 1: Japanese Patent Application Laid-Open No. 2016-72575

Patent Document 2: Japanese Patent Application Laid-Open No. 2013-71873

### SUMMARY

### Problem to be Solved by the Invention

When bonding of the upper surface electrode and the wiring member and bonding of the lower surface electrode and the substrate in the semiconductor element are performed using solder, the lower surface electrode and the substrate need to be bonded firstly, and the upper surface electrode and the wiring member need to be subsequently bonded, thus a takt time gets long.

Recently, there is an increasing demand for a semiconductor device for power control to improve performance and increase a range of an operating temperature, and a semiconductor element formed of wide bandgap semiconductor such as SiC or GaN is being put to practical use. However, a semiconductor element made of SiC is applied to the semiconductor device having the structure described above, there is the following problems.

Firstly, a current density can be increased in the SiC semiconductor element, thus a size of a chip can be reduced. However, when the size of the chip is small, heat resistance increases, thus there is a need to reduce heat resistance of a structure around the chip. The SiC semiconductor element can be operated at a high temperature, however, a melting point of the solder is low, thus an operation temperature is limited by the melting point of the solder.

The present disclosure therefore has been made to solve the above problems, and it is an object to provide a semiconductor device capable of contributing to reduction of manufacturing processes, reduction of heat resistance, and increase of a range of an operation temperature.

### Means to Solve the Problem

A semiconductor device according to the present disclosure includes: an insulating substrate including a conductive pattern on an upper surface; at least one semiconductor element including an upper surface electrode on an upper surface and a lower surface electrode on a lower surface, the lower surface electrode bonded to the conductive pattern of the insulating substrate; and at least one inner wiring member bonded to the upper surface electrode of the semiconductor element, wherein bonding of the lower surface electrode and the conductive pattern and bonding of the upper surface electrode and the inner wiring member are performed by an Al brazing material which is a brazing material made of Al as a main component.

### Effects of the Invention

The present disclosure can contribute to reduction of manufacturing processes, reduction of heat resistance, and increase of a range of an operation temperature of a semiconductor device.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 A cross-sectional view illustrating a configuration of a semiconductor device according to an embodiment 1.

FIG. 2 A plan view illustrating an example of a whole configuration of the semiconductor device according to the embodiment 1.

FIG. 3 A diagram illustrating a configuration example of a switching element.

FIG. 4 A diagram illustrating a configuration example of a reflux diode.

(FIG. 5 A flow chart for explaining a method of manufacturing the semiconductor device according to the embodiment 1.

FIG. 6 A diagram for explaining the method of manufacturing the semiconductor device according to the embodiment 1.

FIG. 7 A plan view illustrating a configuration of a semiconductor device according to an embodiment 2.

FIG. 8 A cross-sectional view illustrating the configuration of the semiconductor device according to the embodiment 2.

FIG. 9 A cross-sectional view illustrating a configuration of a semiconductor device according to an embodiment 3.

### DESCRIPTION OF EMBODIMENT(S)

### Embodiment 1

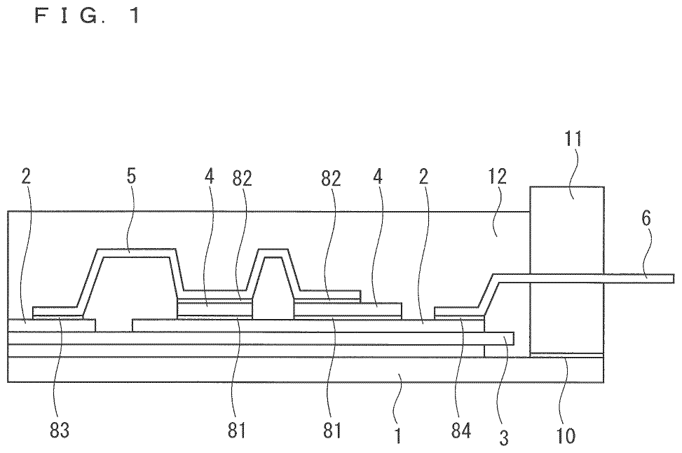

FIG. 1 is a cross-sectional view illustrating a configuration of a semiconductor device according to an embodiment 1. As illustrated in FIG. 1, the semiconductor device according to the embodiment 1 includes a base plate 1, an insulating substrate 3 mounted on the base plate 1 and including a conductive pattern 2 in an upper surface and a lower surface, and a semiconductor element 4 mounted on the conductive pattern 2 of the insulating substrate 3. The base plate 1 illustrated in FIG. 1 has a planar shape, however, the base plate I with a pin fin may be used.

The semiconductor element 4 includes an upper surface electrode (not shown) in the upper surface and a lower surface electrode (not shown) in the lower surface, and the lower surface electrode is bonded to the conductive pattern 2 of the insulating substrate 3 using the Al brazing material 81. An inner wiring member S is bonded to the upper surface electrode of the semiconductor element 4 using an Al brazing material 82. That is to say, both bonding of the lower surface electrode and the conductive pattern 2 and bonding of the upper surface electrode and the inner wiring member 5 are performed by an Al series brazing material.

A composition of the Al brazing material 81 bonding the lower surface electrode and the conductive pattern 2 and a composition of the Al brazing material 82 bonding the upper surface electrode and the inner wiring member 5 may be the same as each other. Accordingly, melting points of the Al brazing material 81 and the Al brazing material 82 can be uniformed. The conductive pattern 2 of the insulating substrate 3, the upper surface electrode and the lower surface electrode of the semiconductor clement 4, and the inner wiring member 5 are preferably formed of a material made of Al as a main component.

In the example in FIG. 1, a part of the inner wiring member 5 is connected to the conductive pattern 2 of the insulating substrate 3 using a brazing material 83. This brazing material 83 needs not necessarily be an Al brazing material, but is preferably an Al brazing material.

A case 11 housing the insulating substrate 3, the semiconductor clement 4, and the inner wiring member 5 is attached on the base plate I using an adhesive agent 10, and the insulating substrate 3, the semiconductor element 4, and the inner wiring member S are sealed by a sealing material 12 filling the case 11. The case 11 includes an outer wiring member 6 as an outer connection terminal integrally formed with the case 1, and the outer wiring member 6 is bonded to the conductive pattern 2 of the insulating substrate 3 using a brazing material 84. This brazing material 84 also needs not necessarily be an Al brazing material, but is preferably an Al brazing material.

A part of the inner wiring member 5 connected to the semiconductor element 4 preferably has a size equal to or larger than an outer shape of the semiconductor element 4. That is to say, a width of a part of the inner wiring member 5 bonded to the upper surface electrode of the semiconductor element 4 is preferably equal to or larger than a width of the semiconductor element 4.

In the semiconductor device according to the embodiment 1, both bonding of the conductive pattern 2 and the semiconductor element 4 and bonding of the semiconductor element 4 and the inner wiring member 5 are performed by an Al brazing material. Heat conductivity of the Al brazing material (170 W/m·k) is higher than that of a conventional solder (55 W/m·k), thus such a configuration can contribute to reduction of heat resistance of the semiconductor device. A melting point of the Al brazing material (approximately 600° C.) is higher than that of a conventional solder (approximately 220° C.), thus such a configuration can contribute to increase of a range of an operation temperature of the semiconductor device. Accordingly, the embodiment 1 is particularly effective for the semiconductor device including the semiconductor element 4 made of wide bandgap semiconductor such as SiC or GaN, for example, which can be operated at a high temperature.

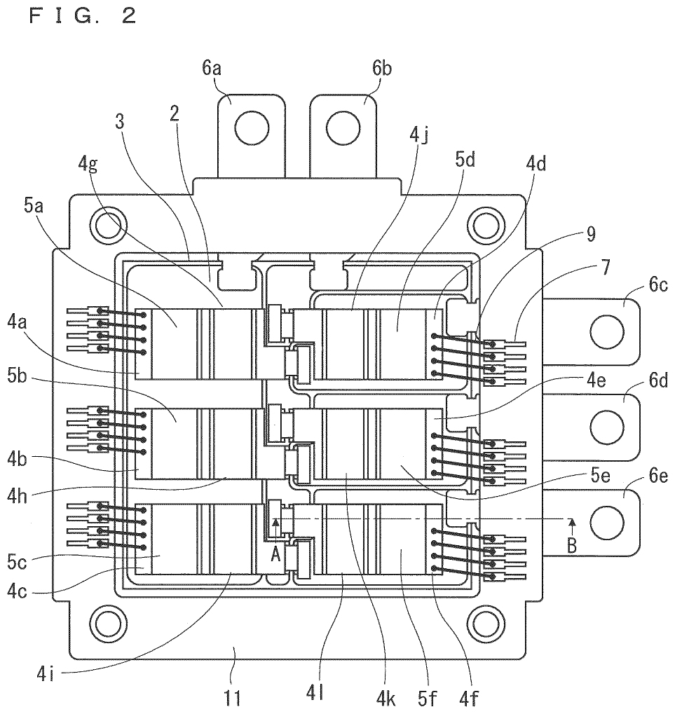

FIG. 2 is a plan view illustrating an example of a whole configuration of the semiconductor device according to the embodiment 1. The cross-sectional view illustrated in FIG. 1 corresponds to a cross section along an A-B line illustrated in FIG. 2.

The semiconductor device illustrated in FIG. 2 constitutes a three-phase inverter circuit, and includes six switching elements 4a to 4f and six reflux diodes 4g to 4l as the semiconductor element 4. Provided as the inner wiring member 5 are an inner wiring member 5a bonded to the switching element 4a and the reflux diode 4g, an inner wiring member 5b bonded to the switching element 4b and the reflux diode 4h, an inner wiring member 5c bonded to the switching element 4c and the reflux diode 4i, an inner wiring member 5d bonded to the switching element 4d and the reflux diode 4j, an inner wiring member 5e bonded to the switching element 4e and the reflux diode 4k, and an inner wiring member 5f bonded to the switching element 4f and the reflux diode 4l. Provided as the outer wiring member 6 are outer wiring members 6a and 6b as input terminals of the inverter and outer wiring members 6c, 6d, and 6e as output terminal terminals of the inverter.

In the example in FIG. 2, all of six inner wiring members 5 bonded to the plurality of semiconductor elements 4 (4a to 4l) have the same shape. Accordingly, cost for the inner wiring member 5 (for example, manufacturing cost or management cost) can be suppressed. All of the plurality of inner wiring members 5 need not have the same shape, however, the effect of cost reduction can be obtained as long as two or more of the plurality of inner wiring members 5 have the same shape.

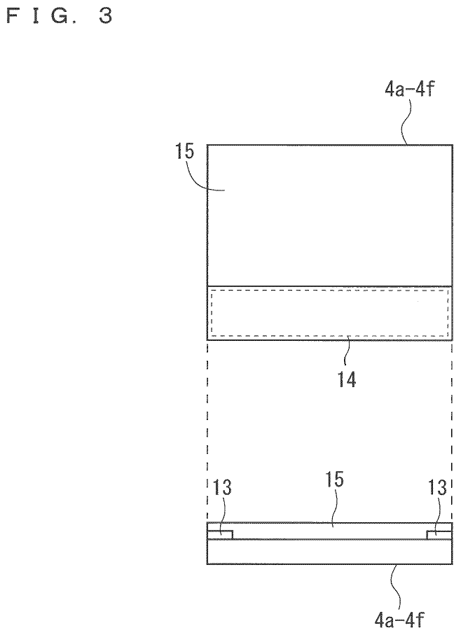

The semiconductor device in FIG. 2 includes a plurality of signal terminals 7 for inputting control signals of the switching elements 4a to 4f. Each signal terminal 7 is connected to a signal pad (signal pad 14 in FIG. 3 described hereinafter) of any of the switching elements 4a to 4f via a bonding wire 9.

The switching elements 4a to 4f are IGBTs or MOSFETs, for example. FIG. 3 is a configuration example of the switching elements 4a to 4f, and illustrates a top view and a cross-sectional view of the switching elements 4a to 4f. In the example in FIG. 3, an insulating layer 13 is formed on an ineffective region in the switching elements 4a to 4f, an electrode (referred to as “Al electrode” hereinafter) 15 formed of an Al series material is formed as the upper surface electrode on a whole upper surface of the switching elements 4a to 4f except for a region of the signal pad 14, and the insulating layer 13 is covered by the Al electrode 15.

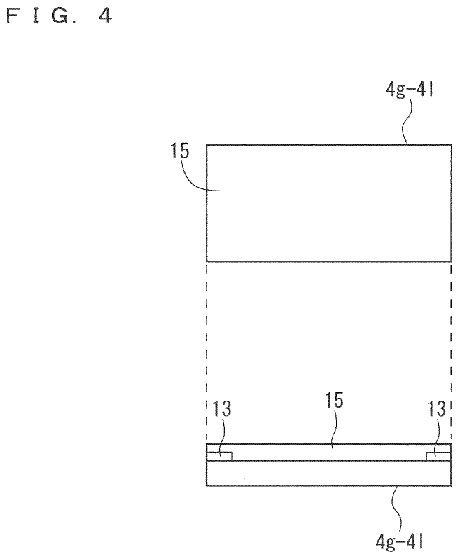

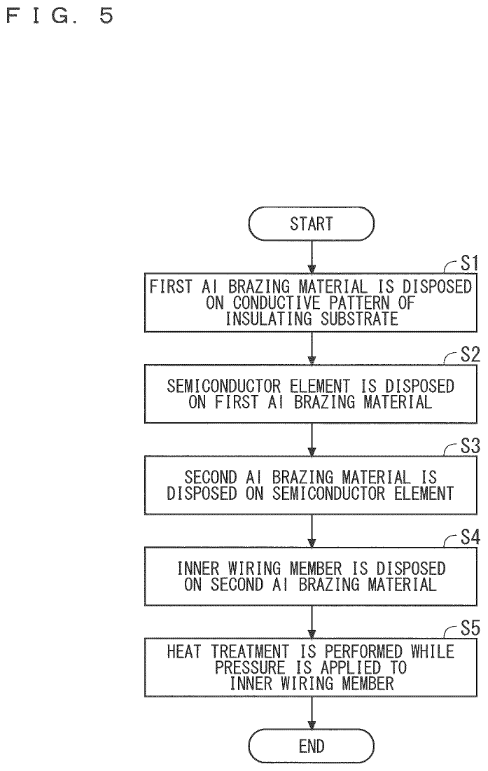

The reflux diodes 4g to 4l are Schottky barrier diodes or PN junction diodes, for example. FIG. 4 is a configuration example of the reflux diodes 4g to 4l, and illustrates a top view and a cross-sectional view of the reflux diodes 4g to 4l. In the example in FIG. 4, the insulating layer 13 is formed on an ineffective region of the reflux diodes 4g to 4l, the Al electrode 15 as the upper surface electrode is formed on the whole upper surface of the reflux diodes 4g to 4l, and the insulating layer 13 is covered by the Al electrode 15.

FIG. 1 to FIG. 4 illustrate the example that the semiconductor element 4 as the switching element and the semiconductor element 4 as the reflux diode are the different elements, however, the semiconductor clement 4 may be a MOSFET or a reverse conducting IGBT (RC-IGBT) including both a built-in switching element and a built-in reflux diode.

Described hereinafter are a method of manufacturing the semiconductor device according to the embodiment 1 and particularly a procedure of bonding the semiconductor element 4 to the insulating substrate 3 and the inner wiring member 5 with reference to a flow chart in FIG. 5.

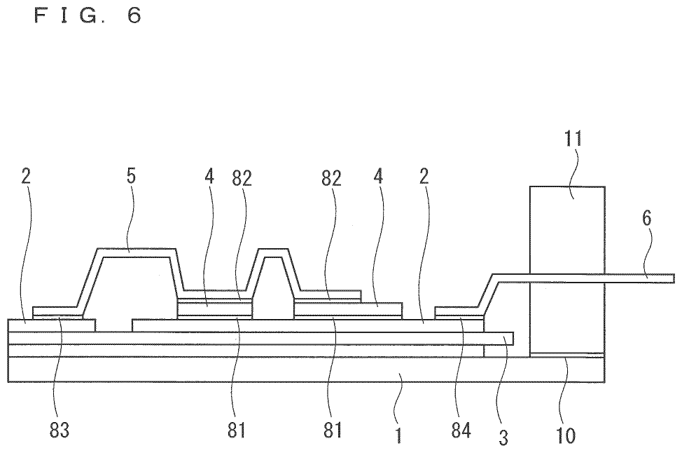

Firstly, the insulating substrate 3 mounted to the base plate 1 is prepared, and the Al brazing material 81 as a first Al brazing material is disposed on the conductive pattern 2 of the insulating substrate 3 (Step S1). Next, the semiconductor element 4 is disposed on the first Al brazing material (the Al brazing material 81) (Step S2). Subsequently, the Al brazing material 82 as a second Al brazing material is disposed on the semiconductor clement 4 (Step S3). Furthermore, the inner wiring member 5 is disposed on the second Al brazing material (the Al brazing material 82) (Step S4). As a result, as illustrated in FIG. 6, the Al brazing material 81, the semiconductor element 4, the Al brazing material 82, and the inner wiring member 5 are stacked in this order on the conductive pattern 2 of the insulating substrate 3. The Al brazing material 81, the semiconductor element 4, the Al brazing material 82, and the inner wiring member 5 disposed in Steps S1 to S4 may be temporarily bonded by an adhesive agent, for example, so that a position thereof is not deviated.

Subsequently, a heat treatment is performed on the inner wiring member 5 while applying pressure from above (Step S5). According to this heat treatment, the semiconductor element 4 and the conductive pattern 2 are bonded by the first Al brazing material (the Al brazing material 81), and the semiconductor element 4 and the inner wiring member 5 are bonded by the second Al brazing material (the Al brazing material 82).

In this manner, according to the semiconductor device of the embodiment 1,bonding of the conductive pattern 2 and the semiconductor element 4 and bonding of the semiconductor element 4 and the inner wiring member 5 can be performed at the same time, thus such a configuration can contribute to reduction of the manufacturing process. When solder is used as the brazing material, a layer for solder bonding (Ni layer, for example) needs to be provided on surfaces of the upper surface electrode and the lower surface electrode of the semiconductor element 4. Thus, such a configuration can contribute to reduction of the manufacturing process also from a viewpoint that such a layer needs to be provided.

When a part of the inner wiring member 5 is bonded to the conductive pattern 2 of the insulating substrate 3 as illustrated in FIG. 1, the brazing material 83 for this bonding is also preferably an Al brazing material. According to such a configuration, bonding of the inner wiring member 5 and the conductive pattern 2 can also be performed together with Step S5. The brazing material 83 also preferably has the same composition as the Al brazing material 81 and the Al brazing material 82.

In the similar manner, the brazing material 84 bonding the outer wiring member 6 and the conductive pattern 2 of the insulating substrate 3 is preferably an Al brazing material. According to such a configuration, bonding of the outer wiring member 6 and the conductive pattern 2 can also be performed together with Step S2, thus such a configuration can further contribute to reduction of the manufacturing process. The brazing material 84 also preferably has the same composition as the Al brazing material 81 and the Al brazing material 82.

It is also applicable that the conductive pattern 2 of the insulating substrate 3 is formed by a clad material of an Al brazing material and an Al alloy to make the Al brazing material 81 and the insulating substrate 3 as an integrated component. “The clad material” indicates a material made up of two or more different types of metal attached to each other. Step SI described above can be omitted, thus such a configuration can further contribute to reduction of the manufacturing process. The number of components is reduced, thus such a configuration can also contribute to reduction of management cost of components.

In the similar manner, it is also applicable that the inner wiring member 5 is formed by a clad material of an Al brazing material and an Al alloy to make the Al brazing material 82 and the inner wiring member 5 as an integrated component. Step S3 described above can be omitted, thus such a configuration can further contribute to reduction of the manufacturing process. The number of components is reduced, thus such a configuration can also contribute to reduction of management cost of components.

It is preferable that the upper surface electrode is formed on almost the whole upper surface of the semiconductor element 4 as illustrated in FIG. 3 and FIG. 4, and furthermore, the width of the part of the inner wiring member 5 bonded to the upper surface electrode of the semiconductor element 4 is equal to or larger than the width of the semiconductor element 4. According to such a configuration, pressure can be applied to the whole semiconductor element 4 in the heat treatment in Step SS described above, thus the semiconductor element 4 can be stably bonded to the conductive pattern 2 and the inner wiring member 5,

When the plurality of semiconductor elements 4 are disposed on the insulating substrate 3 as with the example illustrated in FIG. 2, it is sufficient that the heat treatment in Step S5 is performed on the plurality of semiconductor elements 4 at the same time. Thus, even when the number of the semiconductor elements 4 increases, increase of a takt time is suppressed.

As described above, the semiconductor device according to the embodiment 1 can contribute to reduction of manufacturing processes, reduction of heat resistance, and increase of a range of an operation temperature.

### Embodiment 2

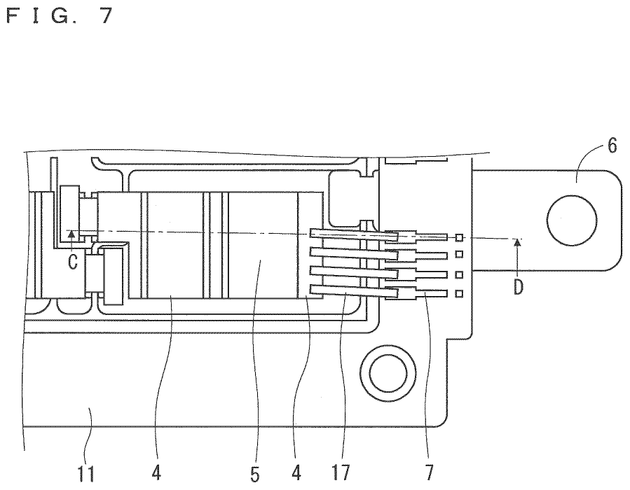

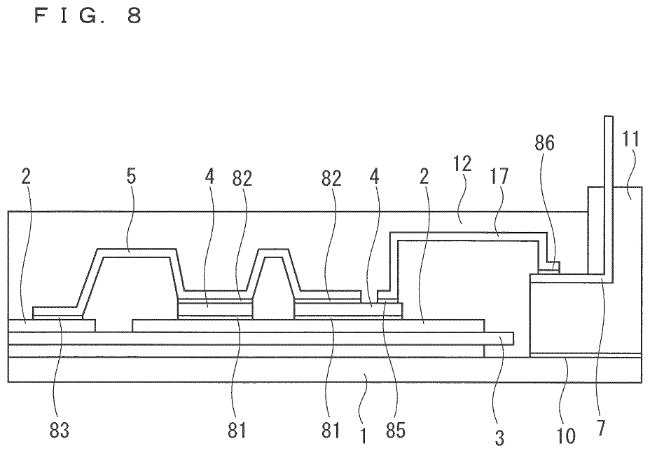

FIG. 7 is a plan view illustrating a configuration of a semiconductor device according to an embodiment 2. FIG. 7 corresponds to a part of the plan view of the semiconductor device illustrated in FIG. 2. The signal pad 14 of the semiconductor element 4 and the signal terminal 7 are connected not by the bonding wire 9 but by a signal wiring member 17. FIG. 8 is a cross-sectional view illustrating the configuration of the semiconductor device according to the embodiment 2, and illustrates a cross section along a C-D line illustrated in FIG. 7, that is to say, a cross section including the signal wiring member 17.

As illustrated in FIG. 7, the signal wiring member 17 and the semiconductor element 4 are bonded by an Al brazing material 85, and the signal wiring member 17 and the signal terminal 7 are bonded by an Al brazing material 86. The Al brazing material 85 and the Al brazing material 86 preferably have the same composition as the Al brazing material 81 and the Al brazing material 82. The signal wiring member 17 is preferably formed of a material containing Al as a main component in the manner similar to the inner wiring member 5.

According to the semiconductor device of the embodiment 2, connection between the semiconductor element 4 and the signal terminal 7 (that is to say, bonding of the semiconductor element 4 and the signal wiring member 17 and bonding of the signal terminal 7 and the signal wiring member 17) can be performed together with Step S5 in FIG. 5, thus such a configuration can further contribute to reduction of the manufacturing process.

### Embodiment 3

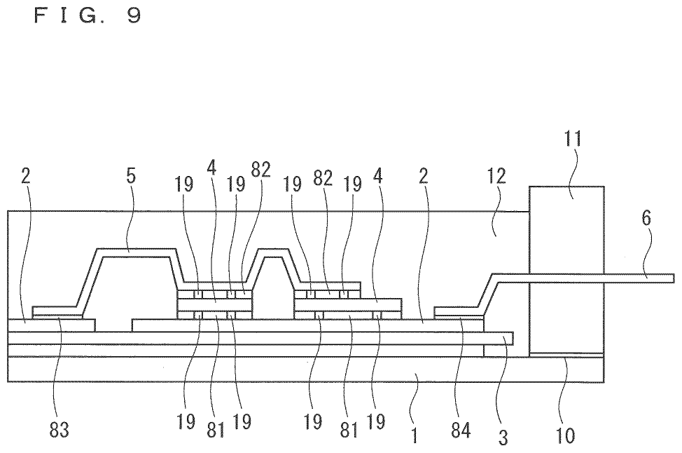

FIG. 9 is a plan view illustrating a configuration of a semiconductor device according to an embodiment 3. In the embodiment 3, as illustrated in FIG. 9, a core material 19 having a constant thickness is inserted into an inner part of the brazing material 81 between the lower surface electrode of the semiconductor element 4 and the conductive pattern 2 and an inner part of the brazing material 82 between the upper surface electrode of the semiconductor element 4 and the inner wiring member 5. Al or a clad material of an Al brazing material and Al alloy, for example, can be used as a material of the core material 19.

According to the semiconductor device of the embodiment 3, the core material 19 is inserted into the Al brazing material 81 and the Al brazing material 82, thus thicknesses of the Al brazing material 81 and the Al brazing material 82 can be ensured, and the thicknesses of the Al brazing material 81 and the Al brazing material 82 are uniformed, thus inclination of the semiconductor element 4 can be prevented. There is no inclination of the semiconductor element 4, thus such a configuration can contribute to stabilization of heat resistance of the semiconductor device and stabilization of manufacture.

Each embodiment can be arbitrarily combined, or each embodiment can be appropriately varied or omitted.

The foregoing description is in all aspects illustrative, and it is therefore understood that numerous modifications not exemplified can be devised.

### EXPLANATION OF REFERENCE SIGNS

1 base plate, 2 conductive pattern, 3 insulating substrate, 4 semiconductor element, 5 inner wiring member, 6 outer wiring member, 7 signal terminal, 81, 82 Al brazing material, 83, 94 brazing material, 85, 86 Al brazing material, 9 bonding wire, 10 adhesive agent, 11 case, 12 sealing material, 13 insulating layer, 14 signal pad, 15 Al electrode, 17 signal wiring member, 19 core material.

1. A semiconductor device, comprising:
an insulating substrate including a conductive pattern on an upper surface;
at least one semiconductor element including an upper surface electrode on an upper surface and a lower surface electrode on a lower surface, the lower surface electrode bonded to the conductive pattern of the insulating substrate; and
at least one inner wiring member bonded to the upper surface electrode of the semiconductor element, wherein
bonding of the lower surface electrode and the conductive pattern and bonding of the upper surface electrode and the inner wiring member are performed by an Al brazing material which is a brazing material made of Al as a main component.

2. The semiconductor device according to claim 1, wherein
the conductive pattern of the insulating substrate, the upper surface electrode and the lower surface electrode of the semiconductor element, and the inner wiring member are formed of a material made of Al as a main component.

3. The semiconductor device according to claim 1, wherein
a width of a part of the inner wiring member bonded to the upper surface electrode is equal to or larger than a width of the semiconductor element.

4. The semiconductor device according to claim 1, wherein
a composition of an Al brazing material bonding the lower surface electrode and the conductive pattern and a composition of an Al brazing material bonding the upper surface electrode and the inner wiring member are a same as each other.

5. The semiconductor device according to claim 1, further comprising
an outer wiring member bonded to the conductive pattern, wherein
bonding of the conductive pattern and the outer wiring member are also performed by an Al brazing material.

6. The semiconductor device according to claim 1, wherein
the semiconductor element further includes a signal pad on an upper surface,
the semiconductor device further includes:
a signal terminal; and
a signal wiring member connecting the signal pad and the signal terminal, wherein
bonding of the signal pad and the signal wiring member and bonding of the signal terminal and the signal wiring member are also performed by an Al brazing material.

7. The semiconductor device according to claim 1, wherein
one of or both the conductive pattern and the inner wiring member are formed by a clad material of an Al brazing material and Al alloy.

8. The semiconductor device according to claim 1, wherein
a core material having a constant thickness is inserted into the brazing material between the lower surface electrode and the conductive pattern and the brazing material between the upper surface electrode and the inner wiring member.

9. The semiconductor device according to claim 1, comprising
the plurality of semiconductor elements.

10. The semiconductor device according to claim 9, wherein
two or more of the plurality of inner wiring members bonded to the plurality of semiconductor elements have a same shape.

11. A method of manufacturing a semiconductor device, comprising steps of:
locating a first Al brazing material on a conductive pattern provided to an insulating substrate;
locating at least one semiconductor element on the first Al brazing material;
locating a second Al brazing material on the semiconductor element;
locating at least one inner wiring member on the second Al brazing material; and
performing a heat treatment on the inner wiring member while applying pressure, thereby bonding the semiconductor element and the conductive pattern by the first Al brazing material and bonding the semiconductor element and the inner wiring member by the second Al brazing material.

12. The method of manufacturing the semiconductor device according to claim 11, wherein
the plurality of semiconductor elements are disposed on the insulating substrate, and
the step of bonding the semiconductor element to the conductive pattern and the inner wiring member is performed on the plurality of semiconductor element at a same time.

13. The method of manufacturing the semiconductor device according to claim 12, wherein
two or more of the plurality of inner wiring members bonded to the plurality of semiconductor elements have a same shape.
